(19) United States
(12) Patent Application Publication
(10) Pub. No.: US 2026/0181929 A1
(43) Pub. Date: Jun. 25, 2026

(54) SEMICONDUCTOR DEVICE AND METHOD OF MANUFACTURING SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Motoya KISHIDA, Kanazawa Ishikawa (JP); Kazutoshi NAKAMURA, Nonoichi Ishikawa (JP)

(21) Appl. No.: 19/310,802

(22) Filed: Aug. 26, 2025

(30) Foreign Application Priority Data
Dec. 23, 2024 (JP) 2024-226406

(51) Int. Cl. H10D 12/00; H10D 12/01; H10D 62/10; H10D 64/00

(52) U.S. Cl. CPC H10D 12/415; H10D 12/032; H10D 12/481; H10D 62/107; H10D 64/111

(57) ABSTRACT

A semiconductor device of an embodiment includes an element region and a termination region. The element region includes circuit elements, such as transistors or the like. The termination region has a first semiconductor region of a first conductivity type, fourth semiconductor regions of a second conductivity type surrounding the element region, a first insulating layer with first and second portions with a fourth semiconductor region therebetween, and a first conductive layer above a fourth semiconductor region. The first and second portions of the first insulating layer each have a first region that is adjacent to the fourth semiconductor region that extends to a depth that is greater than that of a second region of the first and second portions.

### CROSS-REFERENCE TO RELATED APPLICATION(S)

This application is based upon and claims the benefit of priority from Japanese Patent Application No. 2024-226406, filed Dec. 23, 2024, the entire contents of which are incorporated herein by reference.

### FIELD

Embodiments described herein relate generally to a semiconductor device and a method of manufacturing the semiconductor device.

### BACKGROUND

A power semiconductor device is provided with an element region and a termination region surrounding the element region. The element region includes, for example, a semiconductor element, such as an insulated gate bipolar transistor (IGBT) or a metal oxide semiconductor field effect transistor (MOSFET). The termination region alleviates the intensity of the electric field applied to a pn junction at a termination portion of the element region and improves the breakdown voltage of the power semiconductor device. In order to improve the overall breakdown voltage of the power semiconductor device, it is desirable to improve the breakdown voltage of the termination region.

### BRIEF DESCRIPTION OF THE DRAWINGS

FIG. 1 is a schematic top view of a semiconductor device according to an embodiment.

FIG. 2 is a schematic cross-sectional view of a portion of the semiconductor device of an embodiment.

FIG. 3 is a schematic cross-sectional view of a portion of the semiconductor device of an embodiment.

FIG. 4 is a schematic cross-sectional view of a portion of the semiconductor device of an embodiment.

FIG. 5 is a schematic top view of the semiconductor device of an embodiment.

FIG. 6 is a schematic top view of the semiconductor device of an embodiment.

FIG. 7 is an enlarged schematic cross-sectional view of a part of the semiconductor device of an embodiment.

FIG. 8 is an enlarged schematic cross-sectional view of a part of the semiconductor device of an embodiment.

FIG. 9 to FIG. 18 depict aspects of a method for manufacturing a semiconductor device of an embodiment.

FIG. 19 is an enlarged schematic cross-sectional view of a part of a semiconductor device of a comparative example.

FIG. 20 is an enlarged schematic cross-sectional view of a part of a semiconductor device of a first modification of an embodiment.

FIG. 21 is an enlarged schematic cross-sectional view of a part of a semiconductor device of a second modification of an embodiment.

### DETAILED DESCRIPTION

In general, according to an embodiment, a semiconductor device includes a semiconductor layer having a first surface and a second surface opposite the first surface, an element region in the semiconductor layer, and a termination region in the semiconductor layer. The termination region surrounds the element region. The element region includes: a first semiconductor region of a first conductivity type, a second semiconductor region of a second conductivity type between the first semiconductor region and the first surface, a third semiconductor region of the first conductivity type between the second semiconductor region and the first surface, a gate electrode facing the second semiconductor region, a gate insulating film between the second semiconductor region and the gate electrode, a first electrode on the first surface of the semiconductor layer and electrically connected to the third semiconductor region, and a second electrode on the second surface of the semiconductor layer. The termination region includes: the first semiconductor region, a plurality of fourth semiconductor regions of the second conductivity type between the first semiconductor region and the first surface, the fourth semiconductor regions spaced from each other in a first direction (the first direction being a direction outward from the element region towards the termination region), and a first insulating layer comprising first portions and second portions spaced from each other in the first direction. Each fourth semiconductor region is between a first portion and a second portion otherwise adjacent to each other in the first direction. The termination region further includes a first conductive layer with a plurality of portions, each portion of the first conductive layer being on one first portion, one fourth semiconductor region, and one second portion. The one first portion, the one fourth semiconductor region, and the one second portion are between the portion of the first conductive layer and the first semiconductor region. The second electrode is also present in the termination region. Each first portion of the first insulating layer includes a first region and a second region. The first region is adjacent to the fourth semiconductor region. A depth of the first region from the first surface is greater than a depth of the second region from the first surface. Each second portion of the first insulating layer includes a third region and a fourth region. The third region is adjacent to the fourth semiconductor region. A depth of the third region from the first surface is greater than a depth of the fourth region from the first surface.

Hereinafter, certain example embodiments of the present disclosure will be described with reference to the drawings. In the following description, the same or substantially similar components are denoted by the same reference numerals, and the description of these components once described may be omitted as appropriate.

In the present specification, the notations n⁺ type, n type, and n⁻ type, indicate the n-type impurity concentration decreases in the order: n⁺ type, n type, and n⁻ type. The notations p⁺ type, p type, and p⁻ type, indicate the p-type impurity concentration decreases in the order of: p⁺ type, p type, and p-type.

In the present specification, reference to the n-type impurity concentration refers to the effective n-type impurity concentration after compensation (netting). Similarly, reference to the p-type impurity concentration refers to the effective p-type impurity concentration after compensation (netting). For example, when the actual n-type impurity concentration is higher than the actual p-type impurity concentration, the net concentration obtained by subtracting the actual p-type impurity concentration from the actual n-type impurity concentration is taken as the n-type impurity concentration. The same applies to the p-type impurity concentration.

In this specification, the distribution and the absolute value of the impurity concentration of a semiconductor region can be measured by secondary ion mass spectrometry (SIMS), for example. The relative magnitude relationship between the impurity concentrations of the two semiconductor regions can be determined using, for example, scanning capacitance microscopy (SCM). The distribution and the absolute value of the impurity concentration can be measured by using, for example, a spreading resistance analysis (SRA). With SCM and SRA, a relative magnitude relationship and an absolute value of the carrier concentration of the semiconductor region can be obtained. By assuming the activation rate of an impurity, it is possible to obtain the relative magnitude relationship between the impurity concentrations of two different semiconductor regions, the distribution of the impurity concentrations, and the absolute values of the impurity concentrations from the measurement results of the SCM and the SRA.

Unless otherwise specified, the impurity concentration of a semiconductor region is taken as the concentration of the central portion of the semiconductor region.

For example, a scanning electron microscope (SEM) or a transmission electron microscope (TEM) can be used for measuring the shape of a component constituting a semiconductor device, the thickness of a component, the distance between components, and the like in the present specification. In addition, for qualitative analysis and quantitative analysis of the chemical composition of a component included in the semiconductor device in this specification, Rutherford backscattering spectroscopy (RBS), secondary ion mass spectroscopy (SIMS), energy dispersive X-ray spectroscopy (EDX), electron energy loss spectroscopy (EELS), or the like can be used.

### EMBODIMENT

A semiconductor device of an embodiment includes an element region and a termination region surrounding the element region. The element region includes a semiconductor layer, a gate electrode, a gate insulating film, a first electrode, and a second electrode.

A semiconductor layer, having a first surface and a second surface opposite to the first surface, includes a first semiconductor region of a first conductivity type, a second semiconductor region of a second conductivity type provided between the first semiconductor region and the first surface, and a third semiconductor region of the first conductivity type provided between the second semiconductor region and the first surface. The gate electrode faces the second semiconductor region. The gate insulating film is provided between the second semiconductor region and the gate electrode. The first electrode is provided on a side of the first surface of the semiconductor layer and electrically connected to the third semiconductor region. The second electrode is provided on a side of the second surface of the semiconductor layer.

The termination region includes a semiconductor layer, a first insulating layer, a first conductive layer, and a second electrode. The semiconductor layer includes a first semiconductor region and a plurality of fourth semiconductor regions of a second conductivity type provided between the first semiconductor region and the first surface and provided in a direction from the element region toward the termination region. The first insulating layer includes a first portion and a second portion provided with the fourth semiconductor region between the first portion and the second portion in the above described direction. The first conductive layer provided with the first portion, the fourth semiconductor region, and the second portion between the first semiconductor region.

The first portion includes a first region and a second region, the first region is provided between the second region and the fourth semiconductor region in the above described direction, a depth of the first region is deeper than a depth of the second region, the second portion includes a third region and a fourth region, the third region is provided between the fourth region and the fourth semiconductor region in the above described direction, and a depth of the third region is deeper than a depth of the fourth region.

The semiconductor device of this example embodiment is an IGBT 100. The IGBT 100 includes a trench gate type IGBT having gate electrodes in trenches formed in a semiconducting layer. Hereinafter, a case where the first conductivity type is the n-type and the second conductivity type is the p-type will be described as one example.

In the present specification, the term “trench” means a groove provided in a semiconductor layer. A “trench” can be a portion of a semiconductor layer. The “trench” can be filled with, for example, a conductor or an insulator.

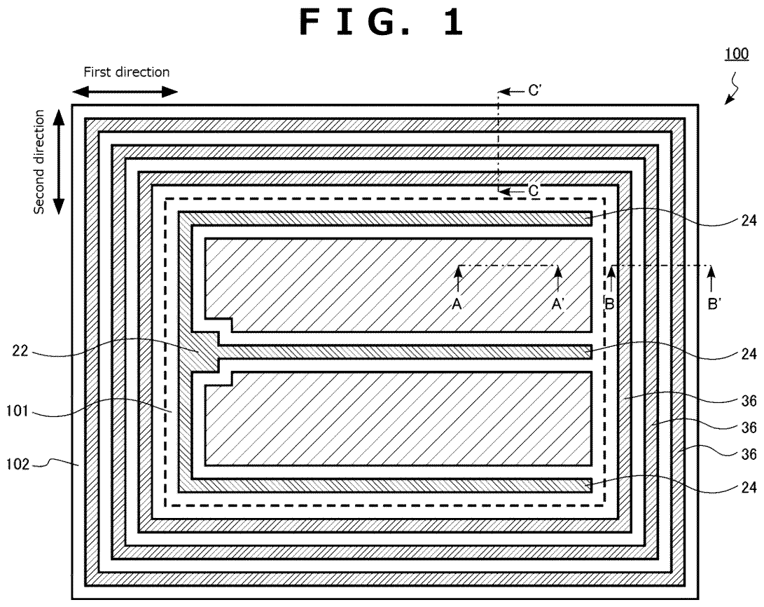

FIG. 1 is a schematic top view of a semiconductor device according to an embodiment.

As shown in FIG. 1, the IGBT 100 includes an element region 101 and a termination region 102. The termination region 102 surrounds the element region 101.

The element region 101 operates as an IGBT. The termination region 102 alleviates the strength of an electric field applied to the pn junction of the termination portion of the element region 101 when the IGBT 100 is in an off state. The termination region 102 is provided for improving the breakdown voltage of the IGBT 100.

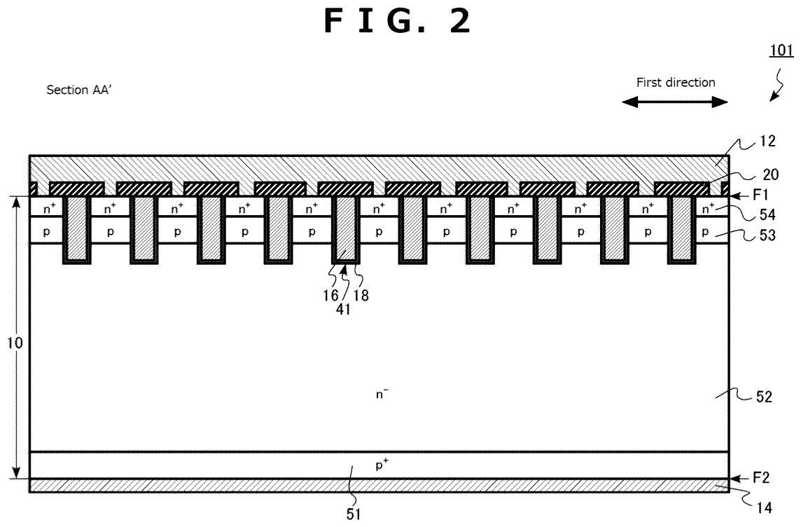

FIG. 2 is a schematic cross-sectional view of a portion of the semiconductor device of an embodiment. FIG. 2 is a schematic cross-sectional view of the element region 101. FIG. 2 is a cross-sectional view taken along line AA′ of FIG. 1.

As shown in FIGS. 1 and 2, the element region 101 includes a semiconductor layer 10, an emitter electrode 12 (first electrode), a collector electrode 14 (second electrode), a gate electrode 16, a gate insulating film 18, an interlayer insulating layer 20, a gate electrode pad 22, and a gate wiring layer 24.

As shown in FIG. 2, a gate trench 41 (trench), a p⁺-type collector region 51 (fifth semiconductor region), an n⁻-type drift region 52 (first semiconductor region), a p-type base region 53 (second semiconductor region), and an n⁺-type emitter region 54 (third semiconductor region) are provided in the semiconductor layer 10 of the element region 101.

The layer 10 has a first surface F1 and a second surface F2 opposite to the first surface F1. The “surface” of the first surface F1 and the second surface F2 is, for example, an interface between a semiconducting layer and an insulating layer or an interface between a semiconducting layer and a conductive layer.

The semiconductor layer 10 is, for example, single crystal silicon (monocrystalline). The film thickness of the semiconductor layer 10 is, for example, 40 μm to 700 μm.

In the present specification, one direction parallel to the first surface F1 is referred to as a first direction. A direction parallel to the first surface F1 but perpendicular to the first direction is referred to as a second direction. In the present specification, the term “depth” is defined as a length in a direction going toward the second surface F2 with reference to the first surface F1.

The emitter electrode 12 is provided on the side of the first surface F1 of the semiconductor layer 10. At least a portion of the emitter layer 12 is in contact with the first surface F1.

The emitter electrode 12 is, for example, a metal. The emitter electrode 12 includes, for example, aluminum.

The emitter electrode 12 is in contact with the emitter region 54. The emitter electrode 12 is electrically connected to the emitter region 54. The emitter electrode 12 is electrically connected to the base region 53.

The collector electrode 14 is provided on the side of the second surface F2 of the semiconductor layer 10. At least a portion of the collector electrode 14 is in contact with the second surface F2.

The collector electrode 14 is, for example, a metal.

The collector electrode 14 is in contact with the collector region 51. The collector electrode 14 is electrically connected to the collector region 51.

The collector region 51 is a p+-type semiconductor region. The collector region 51 is in contact with the second surface F2. The collector region 51 is electrically connected to the collector electrode 14. The collector region 51 is in contact with the collector electrode 14. The collector region 51 serves as a source of holes when the IGBT is in an on state.

The drift region 52 is an n⁻-type semiconductor region. The drift region 52 is provided between the collector region 51 and the first surface F1.

The drift region 52 serves as a path of an on-current when the IGBT is in an on state. The drift region 52 has a function of being depleted when the IGBT is in an off state and maintaining the breakdown voltage of the IGBT.

The base region 53 is a p-type semiconductor region. The base region 53 is provided between the drift region 52 and the first surface F1. The base region 53 sandwiches the drift region 52 with the collector region 51.

In a region of the base region 53 facing the gate electrode 16 to which the gate voltage Vg is applied, an n-type inversion layer is formed when the IGBT is in the on state. The base region 53 functions as a channel region of the transistor.

The emitter region 54 is an n⁺-type semiconductor region. The emitter region 54 is provided between the base region 53 and the first surface F1. The emitter region 54 is in contact with the gate insulating film 18.

The n-type impurity concentration of the emitter region 54 is higher than the n-type impurity concentration of the drift region 52.

The emitter region 54 is in contact with the emitter electrode 12. The emitter region 54 is electrically connected to the emitter electrode 12. The emitter region 54 serves as a source of electrons when the transistor is in an on state.

The gate trenches 41 extend from the first surface F1 into the semiconductor layer 10. The gate trenches 41 are repeatedly provided along the first direction. Each gate trench 41 extends in a second direction parallel to the first surface F1 but perpendicular to the first direction.

The gate trench 41 is in contact with the drift region 52, the base region 53, and the emitter region 54. The gate trench 41 penetrates the base region 53 and reaches the drift region 52.

The depth of the gate trench 41 is, for example, 3 μm to 7 μm.

The gate electrode 16 is provided in the gate trench 41. The gate electrode 16 is electrically connected to the gate electrode pad 22 via the gate wiring layer 24.

The gate electrode 16 is a conductor. The gate electrode 16 is, for example, a semiconductor or a metal. The gate electrode 16 is, for example, amorphous silicon containing an n-type impurity or a p-type impurity, or polycrystalline silicon containing an n-type impurity or a p-type impurity.

The gate insulating film 18 is provided between the gate electrode 16 and the semiconductor layer 10. The gate insulating film 18 is provided between the gate electrode 16 and the base region 53.

The gate insulating film 18 is an insulator. The gate insulating film 18 is, for example, silicon oxide.

The interlayer insulating layer 20 is provided between the gate electrode 16 and the emitter electrode 12. The interlayer insulating layer 20 electrically separates the gate electrode 16 and the emitter electrode 12 from each other.

The interlayer insulating layer 20 is an insulator. The interlayer insulating layer 20 is, for example, silicon oxide.

The gate electrode pad 22 and the gate wiring layer 24 are provided on the interlayer insulating layer 20. As shown in FIG. 1, the gate wiring layer 24 is connected to the gate electrode pad 22.

The gate electrode pad 22 and the gate wiring layer 24 are, for example, metal. The gate electrode pad 22 and the gate wiring layer 24 comprise, for example, aluminum.

The gate electrode pad 22 and the gate wiring layer 24 are formed of, for example, the same material as the emitter electrode 12. The gate electrode pad 22 and the gate wiring layer 24 are formed, for example, in the same process step as the emitter electrode 12.

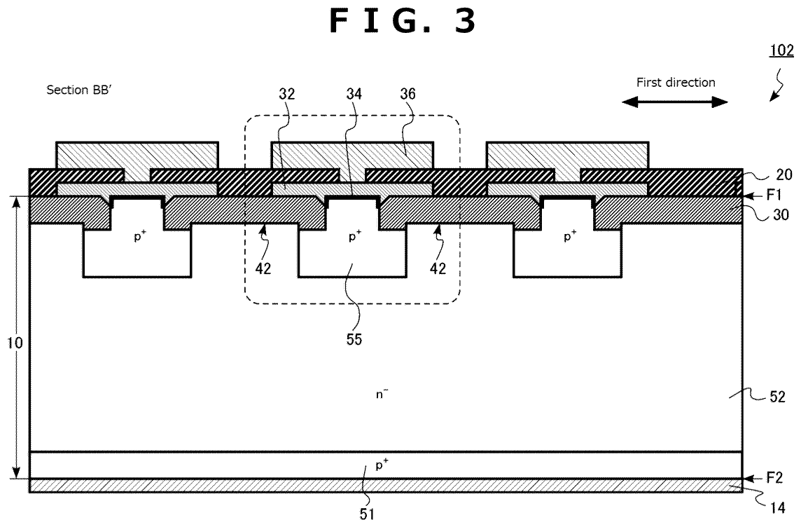

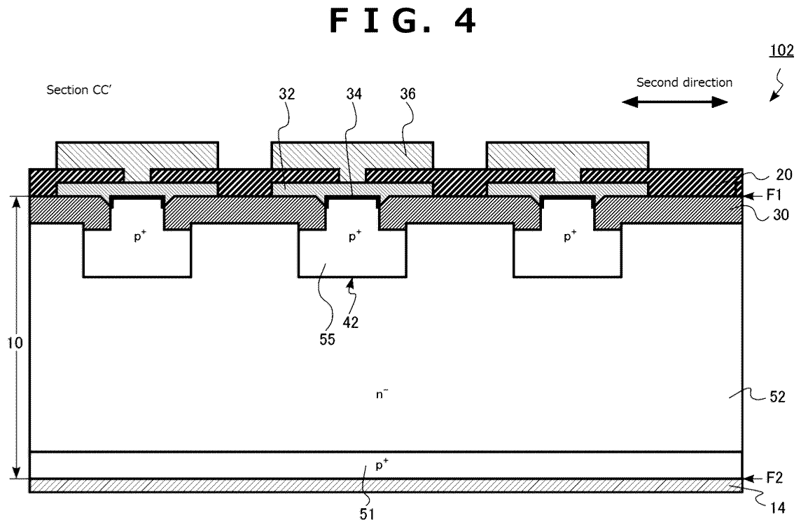

FIGS. 3 and 4 are schematic cross-sectional views of a portion of the semiconductor device of an embodiment. FIG. 3 is a schematic cross-sectional view of the termination region 102. FIG. 3 is a cross-sectional view taken along line BB′ of FIG. 1. FIG. 4 is a schematic cross-sectional view of the termination region 102. FIG. 4 is a cross-sectional view taken along line CC′ of FIG. 1.

As illustrated in FIGS. 1, 3, and 4, the termination region 102 includes a semiconductor layer 10, a collector electrode 14 (second electrode), an interlayer insulating layer 20, a field insulating layer 30 (first insulating layer), a field plate layer 32 (first conductive layer), a field plate insulating film 34 (first insulating film), and a guard ring metal layer 36 (second conductive layer).

In the semiconductor layer 10 of the terminal region 102 (termination region), the field trench 42, a p⁺-type collector region 51 (fifth semiconductor region), an n⁻-type drift region 52 (first semiconductor region), and a p⁺-type guard ring region 55 (fourth semiconductor region) are provided.

The guard ring region 55 is a p⁺-type semiconductor region. The guard ring region 55 is provided between the drift region 52 and the first surface F1.

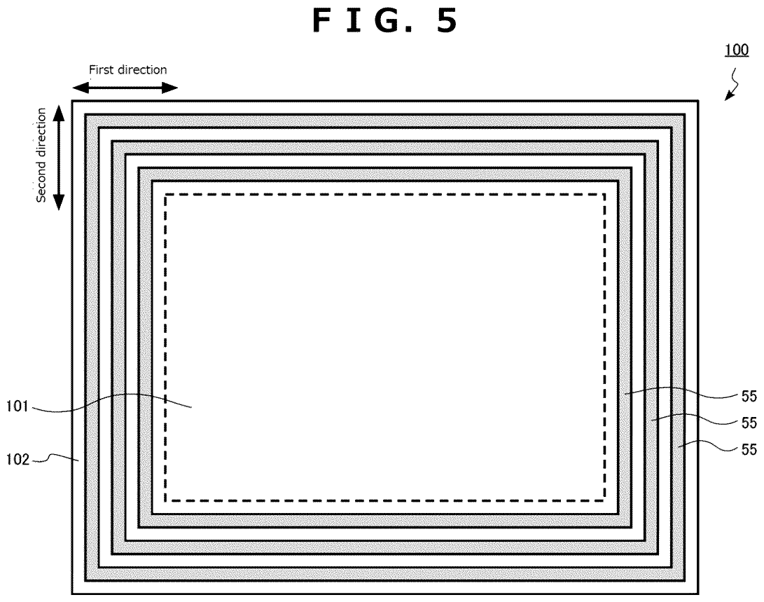

FIG. 5 is a schematic top view of the semiconductor device of an embodiment. FIG. 5 is a view showing a layout pattern of the guard ring region 55.

As shown in FIG. 5, the guard ring region 55 surrounds the element region 101. The guard ring region 55 has an annular shape.

The guard ring regions 55 are repeatedly provided in a direction going from the element region 101 toward the terminal region 102. In FIG. 3, the first direction is an example of a direction going from the element region 101 toward the terminal region 102. In FIG. 4, the second direction is an example of a direction going from the element region 101 toward the terminal region 102. The direction going from the element region 101 toward the termination region 102 corresponds to a direction going from the termination region 102 toward the element region 101.

Although FIGS. 1, 3, 4, and 5 illustrate the case where the number of the guard ring regions 55 is three, the number of the guard ring regions 55 may be two or may be four or more.

The plurality of guard ring regions 55 have a function of alleviating the intensity of an electric field applied to the pn junction at the terminal end of the element region 101 and improving the breakdown voltage of the IGBT 100.

The p-type impurity concentration of each guard ring region 55 is higher than the p-type impurity concentration of the base region 53, for example.

The depth of the guard ring regions 55 is deeper than the depth of the field trench 42. The depth of the guard ring regions 55 is, for example, deeper than the depth of the gate trench 41. The depth of the guard ring regions 55 is, for example, deeper than the depth of the base region 53.

Each guard ring region 55 is electrically floating. In this context, electrically floating means not electrically connected to any voltage source or ground.

The field trench 42 is provided on the side of the first surface F1 of the semiconductor layer 10. The field trenches 42 are repeatedly provided in a direction going from the element region 101 toward the terminal region 102.

The depth of the field trench 42 is, for example, 0.5 μm to 3 μm.

The field insulating layer 30 is provided in the field trench 42. The field insulating layer 30 fills the field trench 42.

The field insulating layer 30 is provided between two adjacent guard ring regions 55 in the direction from the element region 101 toward the terminal region 102. In the direction from the element region 101 toward the terminal region 102, the guard ring region 55 is provided between the field insulating layers 30.

The field insulating layer 30 has a function of electrically separating the field plate layer 32 and the drift region 52, for example.

The field insulating layer 30 is an insulator. The field insulating layer 30 is, for example, an oxide. The field insulating layer 30 is, for example, silicon oxide.

The field plate layer 32 is provided on the field insulating layer 30 and the guard ring region 55. The field insulating layer 30 and the guard ring region 55 are provided between the field plate layer 32 and the drift region 52.

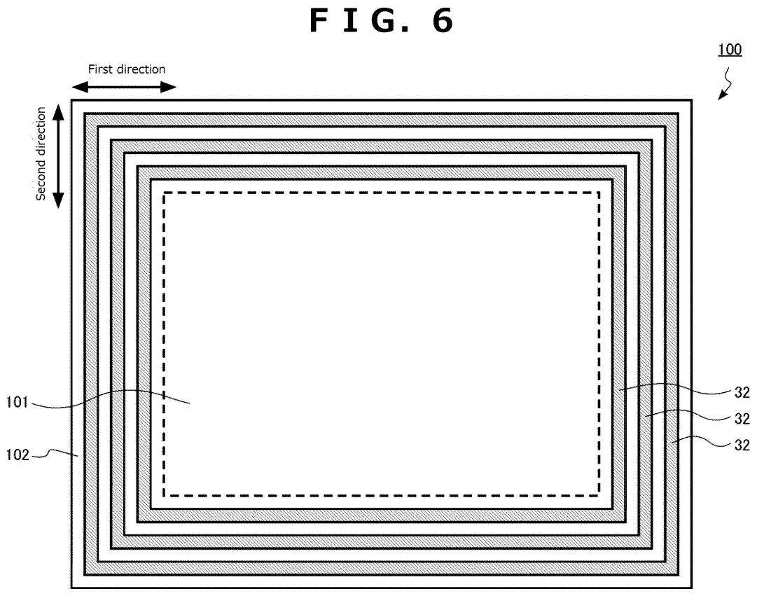

FIG. 6 is a schematic top view of the semiconductor device of an embodiment. FIG. 6 is a view showing a layout pattern of the field plate layer 32.

As shown in FIG. 6, the field plate layer 32 surrounds the element region 101. The field plate layer 32 has an annular shape.

The field plate layers 32 are repeatedly provided in a direction going from the element region 101 toward the terminal region 102. The field plate layers 32 adjacent to each other are separated from each other in the direction going from the element region 101 toward the terminal region 102.

Although FIGS. 1, 3, 4, and 6 illustrate the case where the number of field plate layers 32 is three, the number of field plate layers 32 may be two or may be four or more.

The plurality of field plate layers 32 have a function of alleviating the intensity of an electric field applied to the pn junction at the terminal end of the element region 101 and improving the breakdown voltage of the IGBT 100.

The field plate layer 32 is, for example, a semiconductor or a metal. The gate electrode 16 is, for example, amorphous silicon containing an n-type impurity or a p-type impurity, or polycrystalline silicon containing an n-type impurity or a p-type impurity.

The field plate layer 32 is formed of, for example, the same material as the gate electrode 16. The field plate layer 32 is formed, for example, in the same process step as the gate electrode 16.

The field plate layer 32 is electrically connected to the guard ring region 55. The field plate layer 32 is electrically floating.

The field plate insulating film 34 is provided between the field plate layer 32 and the guard ring region 55. The field plate insulating film 34 is an insulator. The field plate insulating film 34 is, for example, silicon oxide.

The field plate insulating film 34 is formed of, for example, the same material as the gate insulating film 18. The field plate insulating film 34 is formed, for example, in the same process step as the gate insulating film 18.

It is also possible to employ a structure in which the field plate insulating film 34 is omitted and the field plate layer 32 is in contact with the guard ring region 55.

The guard ring metal layer 36 is provided on the guard ring region 55 and the field plate layer 32. The field plate layer 32 is provided between the guard ring metal layer 36 and the guard ring region 55.

As shown in FIG. 1, the guard ring metal layer 36 surrounds the element region 101. The guard ring metal layer 36 has an annular shape.

The guard ring metal layers 36 are repeatedly provided in a direction going from the element region 101 toward the terminal region 102. The guard ring metal layers 36 adjacent to each other are separated from each other in the direction going from the element region 101 toward the terminal region 102.

Although FIGS. 1, 3, and 4 illustrate the case where the number of guard ring metal layers 36 is three, the number of guard ring metal layers 36 may be two or may be four or more.

The plurality of guard ring metallic layers 36 shield an external electric field, stabilize the intensity of the electric field applied to the pn junction at the terminal end of the element region 101, and suppress fluctuations in the breakdown voltage of the IGBT 100.

Each guard ring metal layer 36 is a conductor. The guard ring metal layer 36 is, for example, a metal. The guard ring metal layer 36 comprises, for example, aluminum.

The guard ring metal layer 36 is formed of, for example, the same material as the emitter electrode 12. The guard ring metal layer 36 is formed in the same process step as the emitter electrode 12, for example.

The guard ring metal layer 36 is electrically connected to the field plate layer 32 and the guard ring region 55. The guard ring metal layer 36 is electrically floating.

The interlayer insulating layer 20 is provided between the field plate layer 32 and the guard ring metal layer 36.

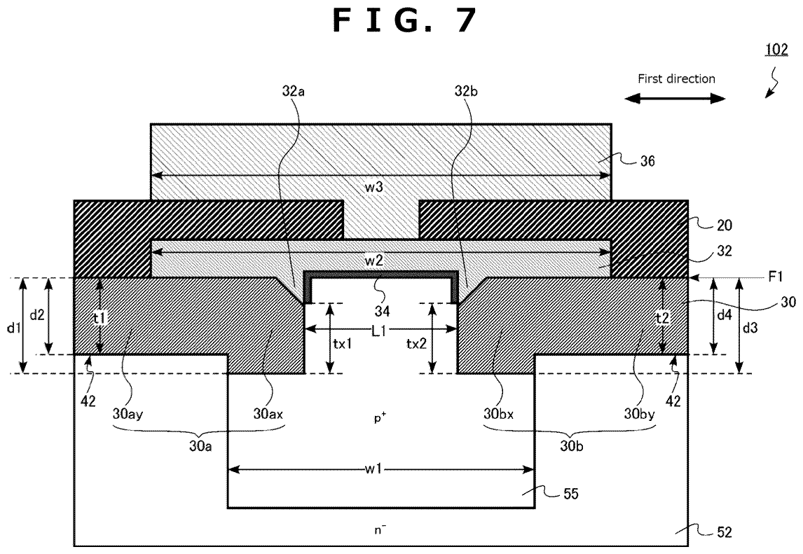

FIG. 7 is an enlarged schematic cross-sectional view of a portion of the semiconductor device of an embodiment. FIG. 7 is an enlarged schematic cross-sectional view of the termination region 102. FIG. 7 is an enlarged schematic cross-sectional view of a portion surrounded by a dotted line in FIG. 3.

The field insulating layer 30 includes a first portion 30a and a second portion 30b. In the direction from element region 101 toward termination region 102, guard ring region 55 is provided between first portion 30a and second portion 30b. In FIG. 7, the direction from the element region 101 toward the termination region 102 is the first direction.

The first portion 30a includes a first deep region 30ax (first region) and a first shallow region 30ay (second region). The second portion 30b includes a second deep region 30bx (third region) and a second shallow region 30by (fourth region).

In the direction from the element region 101 toward the terminal region 102, the first deep region 30ax is provided between the first shallow region 30ay and the guard ring region 55. In the direction from the element region 101 toward the terminal region 102, the second deep region 30bx is provided between the second shallow region 30by and the guard ring region 55.

The depth of the first deep region 30ax (d1 in FIG. 7) is deeper than the depth of the first shallow region 30ay (d2 in FIG. 7). The depth 30ax of the first deep region d1 is, for example, 1.1 times to 1.5 times the depth 30ay of the first shallow region d2.

The depth of the field trench 42 in a portion in contact with the first deep region 30ax is deeper than the depth of the field trench 42 in a portion in contact with the first shallow region 30ay.

The depth of the second deep region 30bx (d3 in FIG. 7) is deeper than the depth of the second shallow region 30by (d4 in FIG. 7). The depth 30bx of the second deep region d3 is, for example, 1.1 times to 1.5 times the depth 30by of the second shallow region d4.

The depth of the field trench 42 in a portion in contact with the second deep region 30bx is deeper than the depth of the field trench 42 in a portion in contact with the second shallow region 30by.

Guard ring region 55 is in contact with first portion 30a and second portion 30b in the direction from element region 101 toward termination region 102. The guard ring region 55 is in contact with the first deep region 30ax and the second deep region 30bx in the direction from the element region 101 toward the terminal region 102.

The thickness (t1 in FIG. 7) of the field insulating layer 30 in the direction perpendicular to the first surface F1 in the first shallow region 30ay is, for example, equal to or less than the depth d2 of the first shallow region 30ay. The thickness of the field insulating layer 30 in the direction perpendicular to the first surface F1 in the second shallow region 30by (t2 in FIG. 7) is, for example, equal to or less than the depth d4 of the second shallow region 30by.

In the direction perpendicular to the first surface F1, the first portion 30a, the guard ring region 55, and the second portion 30b are provided between the field plate layer 32 and the drift region 52.

In the direction perpendicular to the first surface F1, the first portion 30a and the second portion 30b are provided between the field plate layer 32 and the guard ring region 55. In a direction perpendicular to the first surface F1, a first deep region 30ax and a second deep region 30bx are provided between the field plate layer 32 and the guard ring region 55.

The width of each of the guard ring regions 55 in the direction from the element region 101 toward the terminal region 102 (w1 in FIG. 7) is, for example, greater than the distance between the first portion 30a and the second portion 30b of the field insulating layer 30 in the direction from the element region 101 toward the terminal region 102 (L1 in FIG. 7). The width w1 of the guard ring regions 55 is, for example, 1.1 times to 2 times the distance L1 between the first portions 30a and the second portions 30b.

The guard ring region 55 extends around to the bottom of the first portion 30a and the bottom of the second portion 30b.

The length of the field plate layer 32 in the direction from the element region 101 toward the terminal region 102 (w2 in FIG. 7) is larger than the length of the guard ring region 55 in the direction from the element region 101 toward the terminal region 102 (w1 in FIG. 7), for example. The width w2 of the field plate layers 32 are, for example, 1.1 times to 20 times the width w1 of the guard ring regions 55.

The field plate layer 32 includes a first wedge portion 32a (a part of the first conductive layer) and a second wedge portion 32b (another part of the first conductive layer). The first wedge portion 32a and the second wedge portion 32b are portions of the field plate layer 32 that protrude toward the semiconductor element 10. The first wedge portion 32a is in contact with, for example, the first deep region 30ax of the field insulating layer 30. The second wedge portion 32b is in contact with, for example, the second deep region 30bx of the field insulating layer 30.

The guard ring region 55 is provided between the first wedge portion side 32a and the second wedge portion side 32b in the direction from the element region 101 toward the terminal region 102.

The width of the guard ring metallic layers 36 in the direction from the element region 101 toward the terminal region 102 (w3 in FIG. 7) are, for example, larger than the width of the guard ring regions 55 in the direction from the element region 101 toward the terminal region 102 (w1 in FIG. 7). The width w3 of the guard ring metallic layers 36 are, for example, 1.1 to 20 times the width w1 of the guard ring regions 55.

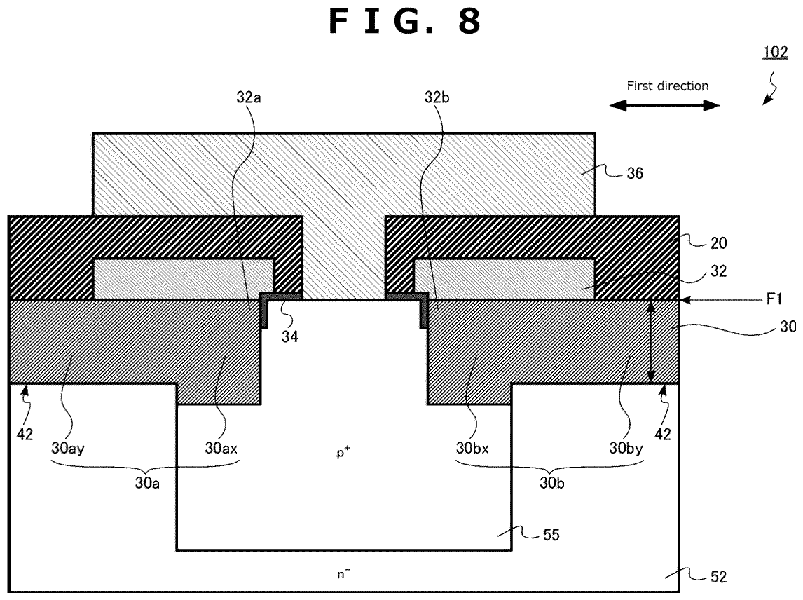

FIG. 8 is an enlarged schematic cross-sectional view of a portion of the semiconductor device of an embodiment. FIG. 8 is an enlarged schematic cross-sectional view of the termination region 102. FIG. 8 is a cross-sectional view taken at position further into the page from the plane depicted of FIG. 7. That is, FIG. 8 is a cross-sectional view of a portion spaced in the second direction from the page plane position of FIG. 7.

As shown in FIG. 8, the guard ring metal layer 36 is in contact with the guard ring region 55. The guard ring metal layer 36 penetrates the interlayer insulating layer 20, the field plate layer 32, and the field plate insulating film 34. The guard ring metal layer 36 is in contact with the guard ring region 55, and is thereby electrically connected to the guard ring region 55. The field plate layer 32 is electrically connected to the guard ring region 55 via, for example, the guard ring metal layer 36 at another position not depicted. The field plate layer 32 is divided into sub-portions spaced from each other in the first direction.

Next, an example of a method for manufacturing a semiconductor device of an embodiment will be described.

A method of manufacturing a semiconductor device according to an embodiment includes forming a ring-shaped semiconductor region of a second conductivity type on a surface of a semiconductor layer by ion-implanting an impurity of a second conductivity type into the semiconductor layer of a first conductivity type, forming a first trench inside the semiconductor region on the surface of the semiconductor layer, where the depth on the side of the semiconductor region is deeper than other parts, and a second trench outside the semiconductor region on the surface of the semiconductor layer, where the depth on the side of the semiconductor region is deeper than other parts,

filling the first trench and the second trench with an insulating film, performing heat treatment to activate the impurity in the semiconductor region, and forming a conductive film on the insulating film and the semiconductor region. The first trench and the second trench are in contact with the semiconductor region, and a distance between the first trench and the second trench in a direction going from an inside to an outside of the semiconductor region is less than a width of the semiconductor region in the same direction.

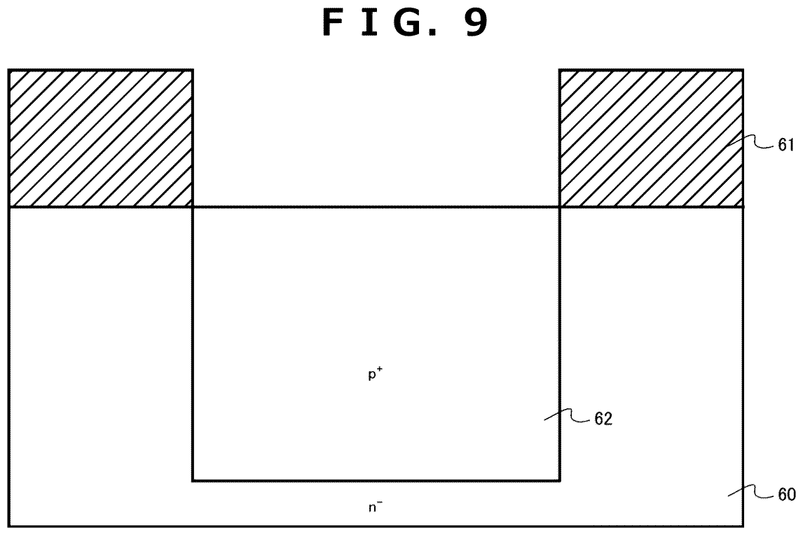

FIGS. 9, 10, 11, 12, 13, 14, 15, 16, 17, and 18 are schematic cross-sectional views illustrating a method for manufacturing a semiconductor device of an embodiment. FIGS. 9 to 18 are drawings corresponding in position to FIG. 7.

First, a first mask material 61 is formed on the surface of an n⁻-type silicon layer 60 (semiconductor layer). The first mask material 61 is, for example, a photoresist formed by using a photolithography method. The first mask material 61 has an annular opening on the surface of the silicon layer 60. A portion of the silicon layer 60 eventually becomes the drift region 52.

Next, boron (B) is ion-implanted into the silicon layer 60 using the first mask material 61 as a mask, thereby forming a p⁺-type silicon region 62 (semiconductor region) (FIG. 9). The silicon region 62 has an annular shape on the surface of the silicon layer 60. The silicon region 62 ultimately becomes the guard ring region 55.

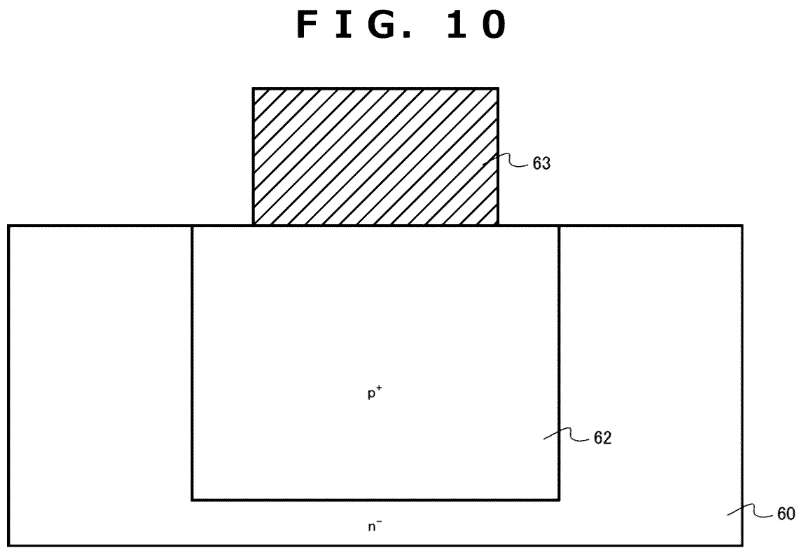

Next, after the first mask material 61 is removed, a second mask material 63 is formed on the surface of the silicon layer 60 (FIG. 10). The second mask material 63 is, for example, a photoresist formed by using a photolithography method. The second mask material 63 has openings inside and outside the silicon region 62. That is, the second mask material 63 has openings on the left side and the right side of the silicon region 62 in FIG. 10.

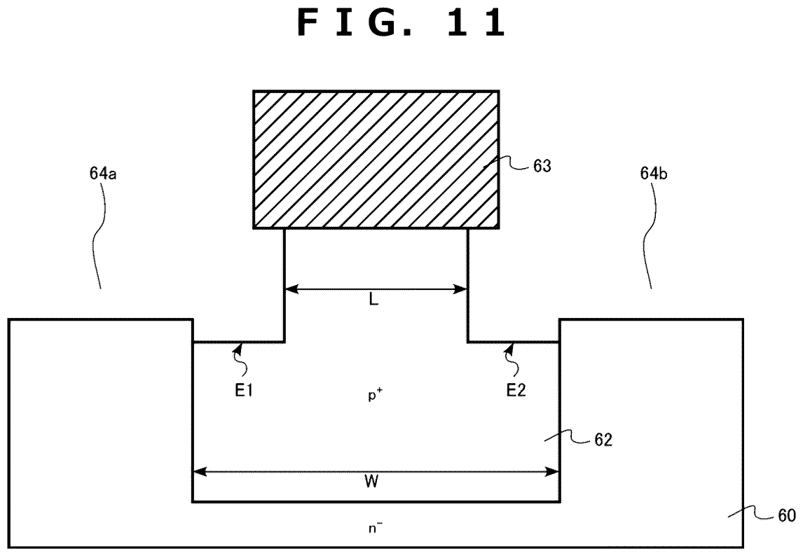

Next, an inner trench 64a (first trench) and an outer trench 64b (second trench) are formed in the silicon layer 60 using the second mask material 63 as a mask (FIG. 11). The inner trench 64a is formed inside the silicon region 62. The outer trench 64b is formed outside the silicon region 62. The inner trench 64a and the outer trench 64b ultimately become the field trench 42.

The inner trench 64a has a portion (E1 in FIG. 11) on the silicon region 62 side deeper than the other portion. In addition, the outer trench 64b has a portion (side E2 in FIG. 11) on the silicon region 62 side deeper than the other portion.

The inner trench 64a and the outer trench 64b are formed by, for example, an isotropic dry etching method. The inner trench 64a and the outer trench 64b are formed by using, for example, a chemical dry etching method (CDE method).

In the silicon region 62, crystal defects generated during the ion implantation of boron (B) are present. For example, when etching is performed by an isotropic dry etching method, the etching rate of a portion where a crystal defect exists is higher than that of the other portion.

In this case, as shown in FIG. 11, the depth of the portion (E1 in FIG. 11) of the inner trench 64a on the silicon region 62 side is deeper than the depth of the other portion of the inner trench 64a. The depth of the inner trench 64a formed in the silicon region 62 is deeper than the depth of the inner trench 64a formed in the other silicon layer 60.

Further, as shown in FIG. 11, the depth of the portion (E2 in FIG. 11) of the outer trench 64b on the silicon region 62 side is deeper than the depth of the other portion of the outer trench 64b. The depth of the outer trench 64b formed in the silicon region 62 is deeper than the depth of the outer trench 64b formed in the other silicon layer 60.

The inner trench 64a and the outer trench 64b are in contact with the silicon region 62. The length (L in FIG. 11) between the inner trench 64a and the outer trench 64b in the direction from the inside to the outside of the silicon region 62 is less than the width (W in FIG. 11) of the silicon region 62 in the direction from the inside to the outside of the silicon region 62.

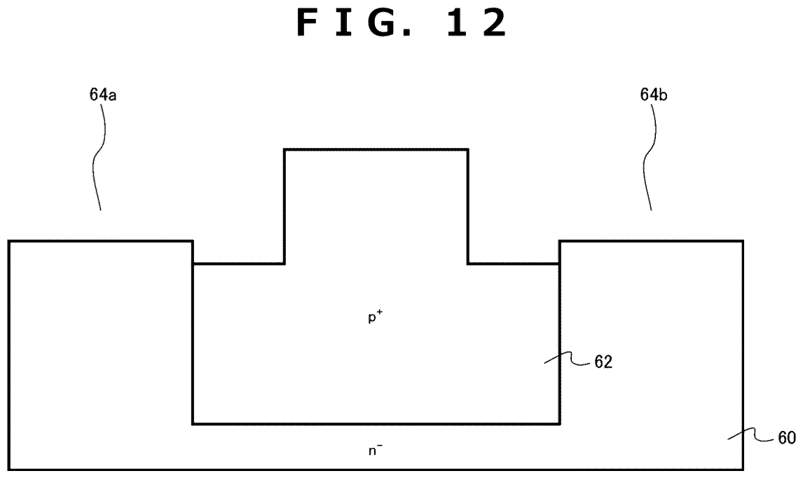

Next, the second mask material 63 is removed (FIG. 12).

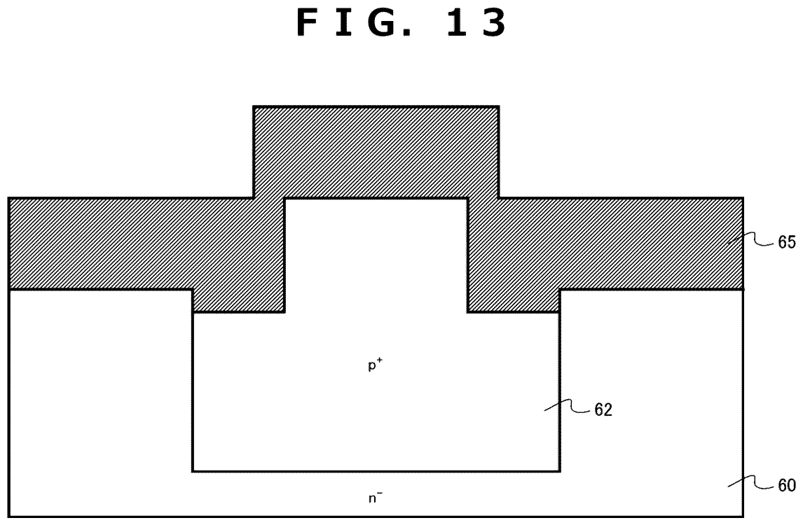

Next, the inner trench 64a and the outer trench 64b are filled with a first silicon oxide film 65 (insulating film) (FIG. 13). The first silicon oxide film 65 is formed by using, for example, a plasma-enhanced chemical vapor deposition method (PECVD method). A part of the first silicon oxide film 65 ultimately becomes the field insulating layer 30.

Next, heat treatment for activating boron (B) in the silicon region 62 is performed. The heat treatment is performed, for example, at a temperature of 1000° C. to 1100° C. in an inert gas atmosphere. By activating boron (B) in the silicon region 62, crystal defects in the silicon region 62 are recovered (healed).

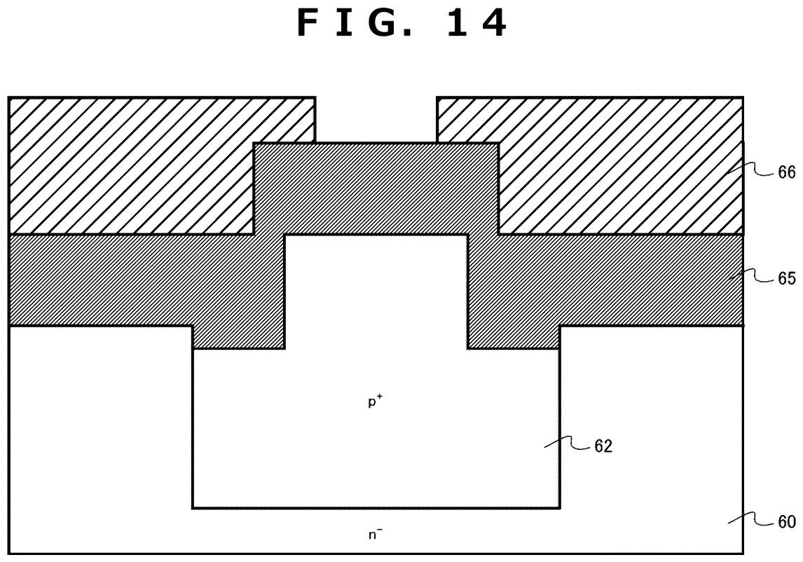

Next, a third mask material 66 is formed on the first silicon oxide film 65 (FIG. 14). The third mask material 66 is, for example, a photoresist formed by photolithography. The third mask material 66 has an annular opening on the surface of the first silicon oxide film 65.

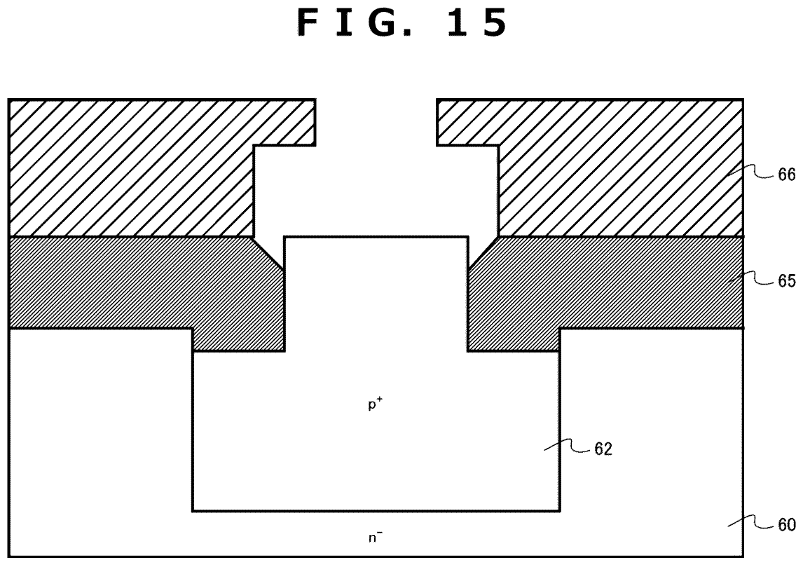

Next, a part of the first silicon oxide film 65 is removed using the third mask material 66 as a mask to expose the silicon region 62 (FIG. 15). The first silicon oxide film 65 is removed by, for example, wet etching. When the first silicon oxide film 65 is removed, a part of the side surface of the silicon region 62 is exposed.

Thereafter, the third mask material 66 is removed, and the element region 101 is formed in a region) of the silicon layer 60. That is, a structure that ultimately becomes the p-type base region 53, the n⁺-type emitter region 54, the gate trench 41, the gate insulating film 18, and the gate electrode 16 is formed in a region of the silicon layer 60 that is not specifically depicted in FIG. 15.

Next, a second silicon oxide film 67 is formed on the surface of the silicon region 62. The second silicon oxide film 67 is formed by, for example, a thermal oxidation method. The second silicon oxide film 67 may be formed simultaneously with the formation of the gate insulating film 18 in the element region 101.

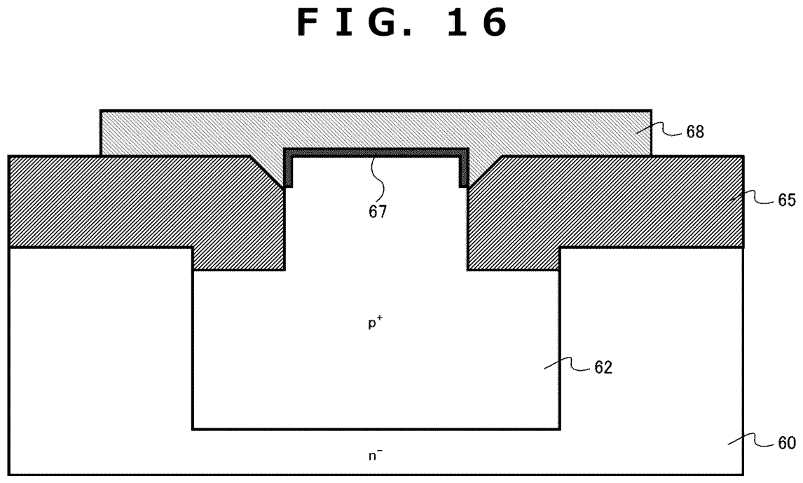

Next, a polycrystalline silicon film 68 (conductive film) containing phosphorus (P) as an impurity is formed on the second silicon oxide film 67 (FIG. 16). The polycrystalline silicon film 68 is formed by, for example, deposition of a film by a chemical vapor deposition method (CVD method) and patterning using a dry etching method. The polycrystalline silicon film 68 ultimately becomes the field plate layer 32. The polycrystalline silicon film 68 may be formed simultaneously with the gate electrode 16 in the element region 101.

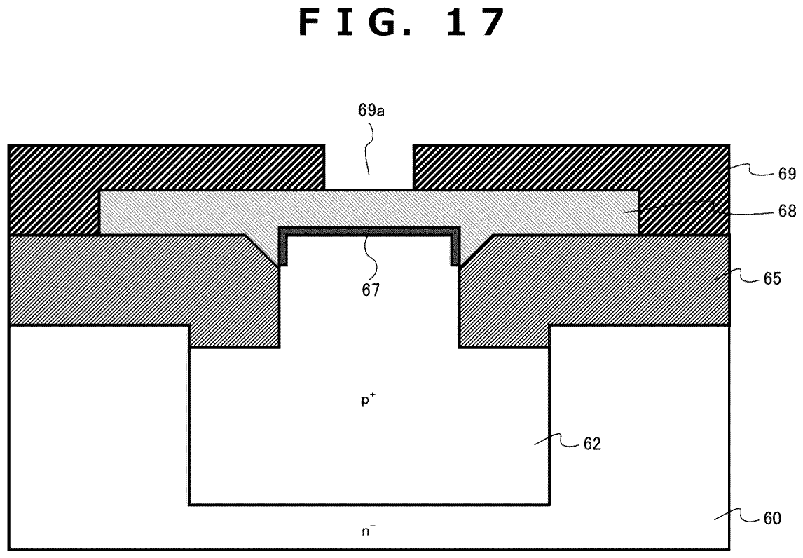

Next, a third silicon oxide film 69 having an opening 69a is formed on the polycrystalline silicon film 68 (FIG. 17). The third silicon oxide film 69 is formed by, for example, depositing a film by a CVD method and opening the opening 69a by a dry etching method. A part of the third silicon oxide film 69 ultimately becomes the interlayer insulating layer 20.

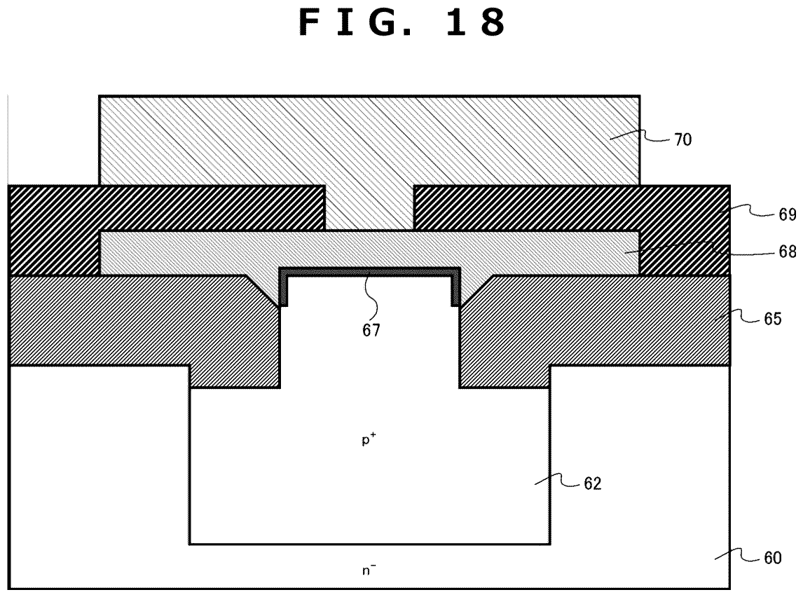

Next, an aluminum film 70 is formed on the third silicon oxide film 69 (FIG. 18). The aluminum film 70 is formed by, for example, deposition of a film by a sputtering method and patterning using a dry etching method. A part of the aluminum film 70 ultimately becomes the guard ring metal layer 36. For example, the other portion of the aluminum film 70 becomes the emitter electrode 12, the gate electrode pad 22, and the gate wiring layer 24.

Thereafter, a silicon region that ultimately becomes the collector region 51 and a metal film that ultimately becomes the collector electrode 14 are formed on the back surface side of the silicon layer 60 by using known process steps.

The IGBT 100 can be formed by the above manufacturing method.

Next, the functions and effects of the semiconductor device and the method for manufacturing the semiconductor device according to the embodiment will be described.

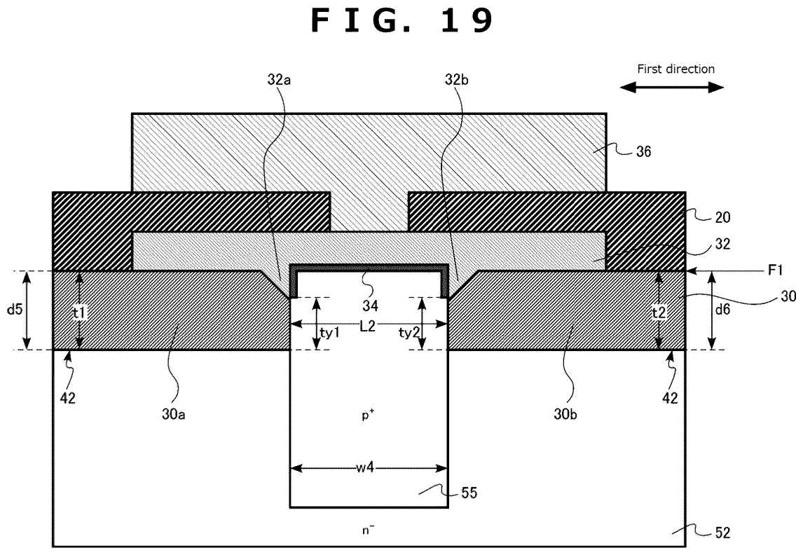

FIG. 19 is an enlarged schematic cross-sectional view of a portion of a semiconductor device of a comparative example. FIG. 19 is a drawing corresponding in general to FIG. 7.

The semiconductor device of the comparative example is different from the semiconductor device of an embodiment in that the depth of the field insulating layer 30 is constant. The semiconductor device of the comparative example is different from the semiconductor device of an embodiment in that the first portion and the second portion are not provided between the first conductive layer and the fourth semiconductor region in the direction perpendicular to the first surface. The semiconductor device of the comparative example is different from the semiconductor device of an embodiment in that the width of the fourth semiconductor region in the direction from the element region toward the terminal region is equal to the distance between the first portion and the second portion in the direction.

In the IGBT of the comparative example, the field insulating layer 30 includes a first portion 30a and a second portion 30b, similarly to the IGBT 100 of an embodiment. In the IGBT of the comparative example, the depth of the first portion 30a (d5 in FIG. 19) and the depth of the second portion 30b (d6 in FIG. 19) are constant. In the IGBT of the comparative example, the depth of the field trench 42 in contact with the first portion side 30a and the depth of the field trench 42 in contact with the second portion side 30b are constant.

In the IGBT of the comparative example, the thickness of the field insulating layer 30 in the portion where the first portion 30a is in contact with the guard ring region 55 (ty1 in FIG. 19) is less than the thickness of the field insulating layer 30 in the other portion of the first portion 30a (t1 in FIG. 19). The thickness of the field insulating layer 30 in the portion where the second portion 30b is in contact with the guard ring region 55 (ty2 in FIG. 19) is less than the thickness of the field insulating layer 30 in the other portion of the second portion 30b (t2 in FIG. 19).

In the IGBT of the comparative example, the first portion 30a and the second portion 30b are not provided between the field plate layer 32 and the guard ring region 55 in the direction perpendicular to the first surface F1. In the IGBT of the comparative example, the width of the guard ring regions 55 in the direction from the element region 101 toward the terminal region 102 (w4 in FIG. 19) are equal to the distances between the first portions 30a and the second portions 30b of the field insulating layers 30 in the direction from the element region 101 toward the terminal region 102 (L2 in FIG. 19).

In the IGBT of the comparative example, the guard ring region 55 does not extend to the bottom of the first portion 30a and the bottom of the second portion 30b, unlike in the IGBT 100.

In the IGBT of the comparative example, the thickness of the field insulating layer 30 in the portion in contact with the guard ring region 55 becomes thinner, and thus the strength of the electric field in the vicinity of the end portion of the field insulating layer 30 is increased. Therefore, the breakdown voltage of the IGBT of the comparative example decreases.

In the IGBT 100, the first portion 30a includes a first deep region 30ax (first region) and a first shallow region 30ay (second region). The second portion 30b includes a second deep region 30bx (third region) and a second shallow region 30by (fourth region).

In the IGBT 100, the depth of the first deep region 30ax (d1 in FIG. 7) is deeper than the depth of the first shallow region 30ay (d2 in FIG. 7). Therefore, the thickness of the field insulating layer 30 at the portion where the first portion 30a is in contact with the guard ring region 55 (tx1 in FIG. 7) is greater than the thickness of the field insulating layer 30 at the portion where the first portion 30a of the IGBT of the comparative example is in contact with the guard ring region 55 (ty1 in FIG. 19).

Similarly, the depth of the second deep region 30bx (d3 in FIG. 7) is greater (deeper) than the depth of the second shallow region 30by (d4 in FIG. 7). Therefore, the thickness (tx2 in FIG. 7) of the field insulating layer 30 in the portion where the second portion 30b is in contact with the guard ring region 55 is larger than the thickness (ty2 in FIG. 19) of the field insulating layer 30 in the portion where the second portion 30b of the IGBT of the comparative example is in contact with the guard ring region 55.

In the IGBT 100, the thickness of the field insulating layer 30 in the portion in contact with the guard ring region 55 becomes thicker, and thus the strength of the electric field in the vicinity of the end portion of the field insulating layer 30 is alleviated. Therefore, the breakdown voltage of the IGBT 100 can be improved (increased).

From the viewpoint of improving the breakdown voltage of the IGBT 100, the depth d1 of the first deep region 30ax is preferably at least 1.1 times the depth d2 of the first shallow region 30ay. From the same viewpoint, the depth d3 of the second deep region 30 bx is preferably at least 1.1 times the depth d4 of the second shallow region 30by.

Furthermore, in the IGBT 100, the guard ring region 55 extends around to the bottom portion of the first portion 30a of the field insulating layer 30 and the bottom portion of the second portion 30b of the field insulating layer 30. The guard ring region 55 extends around to the bottom portion of the first portion 30a and the bottom portion of the second portion 30b, and thereby, the strength of the electric field in the vicinity of the end portion of the field insulating layer 30 is further alleviated. Therefore, the breakdown voltage of the IGBT 100 may be further improved.

From the viewpoint of increasing the wraparound of the guard ring region 55 to the bottom portion of the field insulating layer 30 to improve the breakdown voltage of the IGBT 100, the width w1 of the guard ring region 55 is preferably at least 1.1 times, more preferably at least 1.2 times, and even more preferably at least 1.5 times the distance L1 between the first portion 30a and the second portion 30b.

In the method of manufacturing the IGBT 100 according to an embodiment, the end portion of each of the inner trench 64a and the outer trench 64b, which ultimately become the field trench 42, on the side of the silicon region 62 is formed to be deep. Therefore, the IGBT 100 can be manufactured.

In particular, before performing the heat treatment for activating boron (B) in the silicon region 62, the inner trench 64a and the outer trench 64b are formed by using the CDE method. That is, the silicon layer 60 is etched by the CDE method before the crystal defects in the silicon region 62 generated during the ion implantation of boron (B) are recovered. Since the etching rate of the portion where the crystalline defects exist is higher than that of the other portion, the end portion of each of the inner trench 64a and the outer trench 64b on the side of the silicon region 62 can be formed to be deeper.

As described above, according to the embodiment, an IGBT that can improve the breakdown voltage can be provided.

### (First Modification)

A semiconductor device according to a first modification is different from the semiconductor device according to the already described embodiment in that the first portion and the second portion are not provided between the first conductive layer and the fourth semiconductor region in the direction perpendicular to the first surface. Further, the semiconductor device according to the first modification is different from the semiconductor device according to the already described embodiment in that the width of the fourth semiconductor region in the direction from the element region toward the terminal region is equal to the distance between the first portion and the second portion in the direction.

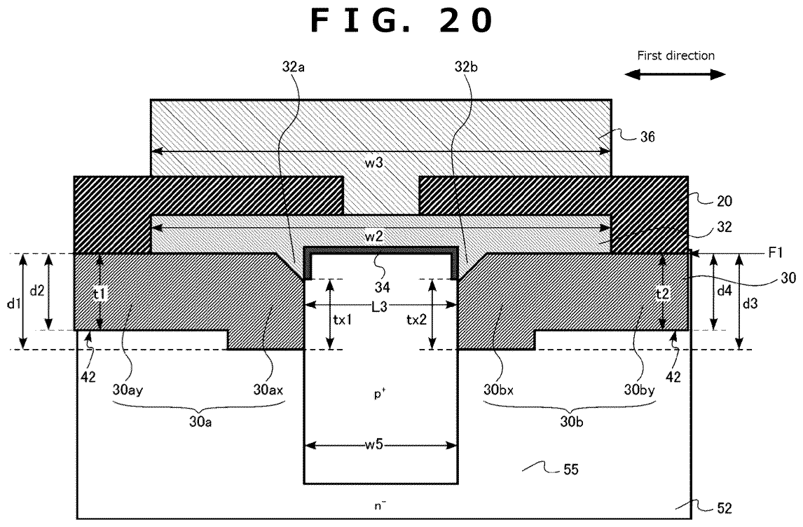

FIG. 20 is an enlarged schematic cross-sectional view of a portion of a semiconductor device of a first modification. In general, FIG. 20 is a diagram corresponding to FIG. 7.

In the IGBT of this first modification, the first portion 30a and the second portion 30b are not provided between the field plate layer 32 and the guard ring region 55 in the direction perpendicular to the first surface F1. In the IGBT of the first modification, the width of the guard ring regions 55 in the direction from the element region 101 toward the terminal region 102 (w5 in FIG. 20) is equal to the distance between the first portions 30a and the second portions 30b of the field insulating layers 30 in the direction from the element region 101 toward the terminal region 102 (L3 in FIG. 20).

Unlike the side IGBT 100 of already described example embodiment, in this first modification the guard ring region 55 does not extend to the bottom portion of the first portion 30a and the bottom portion of the second portion 30b.

In the IGBT of this first modification, the thickness of the field insulating layer 30 in the portion in contact with the guard ring region 55 is increased, and thus the strength of the electric field in the vicinity of the end portion of the field insulating layer 30 is alleviated, similarly to the IGBT 100 portion of the already described embodiment. Therefore, the breakdown voltage of the IGBT of the first modification can be improved (increased).

In the IGBT of the first modification, the inner trench 64a and the outer trench 64b are formed by using, for example, a reactive ion etching method (RIE method). The IGBT of the first modification can be manufactured by selecting, as the RIE conditions, conditions under which the end portions of the inner trench 64a and the outer trench 64b on the silicon region 62 side become deeper.

### (Second Modification)

A semiconductor device according to a second modification is different from the semiconductor device according to the already described embodiment in that a part of the first conductive layer and another part of the first conductive layer sandwiching the fourth semiconductor region are not provided.

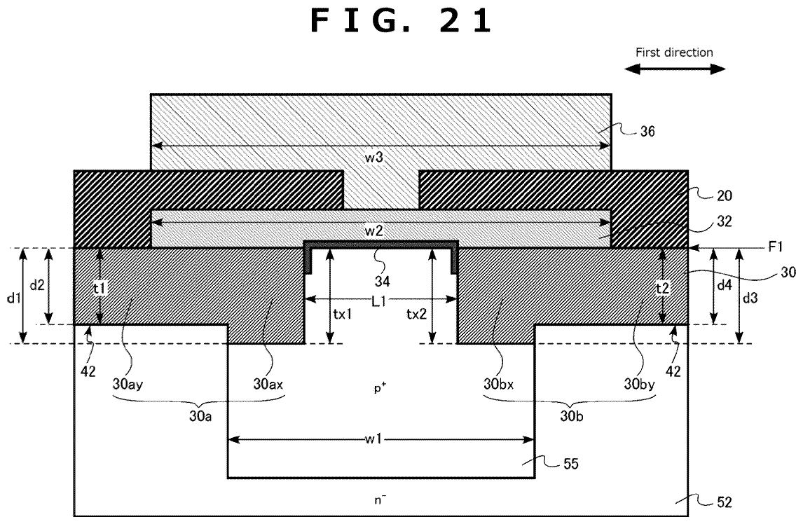

FIG. 21 is an enlarged schematic cross-sectional view of a portion of a semiconductor device of a second modification. In general, FIG. 21 is a diagram corresponding to FIG. 7.

In the IGBT of this second modification, the field plate layer 32 does not include the first wedge portion 32a and the second wedge portion 32b.

In the IGBT of the second modification, similarly to the IGBT 100 of the already described embodiment, the thickness of the field insulating layer 30 in the portion in contact with the guard ring region 55 is increased, and the guard ring region 55 extends around to the bottom portion of the first portion 30a and the bottom portion of the second portion 30b, so that the intensity of the electric field in the vicinity of the end portion of the field insulating layer 30 is alleviated. Therefore, the breakdown voltage of the IGBT of the second modification can be improved (increased).

In the IGBT of this second modification, the thickness of the field insulating layer 30 in a portion in contact with the guard ring region 55 (tx1 and tx2 in FIG. 21) is further increased as compared to the IGBT 100 of an embodiment. Therefore, the breakdown voltage of the IGBT of the second modification may be further improved as compared with the IGBT 100 of the already described embodiment.

The IGBT of the second modification can be formed by using a chemical mechanical polishing method (CMP method) instead of the wet etching method when a part of the first silicon oxide film 65 is removed to expose the silicon region 62.

According to this second modification example, it is possible to provide a semiconductor device having improved breakdown voltage and a method for manufacturing the semiconductor device.

In an embodiment, the semiconductor layer is single crystal silicon, but the semiconductor layer is not limited to single crystal silicon. For example, other single crystal semiconductors such as single crystal silicon carbide may be used.

In an embodiment, the first conductivity type is the n-type and the second conductivity type is the p-type, but it is also possible for the first conductivity type to be p-type and the second conductivity type to be n-type.

In an embodiment, the semiconductor device is an IGBT, but the semiconductor device is not limited to an IGBT and may be, for example, a reverse-conducting IGBT (RC-IGBT) in which an IGBT and a freewheeling diode are formed on the same semiconductor chip. In other examples, the semiconductor device may be a MOSFET.

In an embodiment, the semiconductor device is a trench gate type IGBT, but, in other examples, the semiconductor device may be a planar gate type IGBT.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. For example, the components of one embodiment may be replaced or modified with the components of another embodiment. These embodiments and modifications thereof are included in the scope and gist of the invention, and are included in the invention described in the claims and the equivalent scope thereof.

What is claimed is:

1. A semiconductor device, comprising:
a semiconductor layer having a first surface and a second surface opposite the first surface;
an element region of the semiconductor layer; and
a termination region of the semiconductor layer, the termination region surrounding the element region, wherein
the element region includes:
a first semiconductor region of a first conductivity type,
a second semiconductor region of a second conductivity type between the first semiconductor region and the first surface,
a third semiconductor region of the first conductivity type between the second semiconductor region and the first surface,
a gate electrode facing the second semiconductor region,
a gate insulating film between the second semiconductor region and the gate electrode,
a first electrode on the first surface of the semiconductor layer and electrically connected to the third semiconductor region, and
a second electrode on the second surface of the semiconductor layer,
the termination region includes:
the first semiconductor region,
a plurality of fourth semiconductor regions of the second conductivity type between the first semiconductor region and the first surface, the fourth semiconductor regions spaced from each other in a first direction, the first direction being a direction outward from the element region towards the termination region,
a first insulating layer comprising first portions and second portions spaced from each other in the first direction, each fourth semiconductor region being between a first portion and a second portion otherwise adjacent to each other in the first direction,
a first conductive layer with a plurality of portions, each portion of the first conductive layer being on one first portion, one fourth semiconductor region, and one second portion, the one first portion, the one fourth semiconductor region, and the one second portion being between the portion of the first conductive layer and the first semiconductor region, and
the second electrode, wherein
each first portion of the first insulating layer includes a first region and a second region, the first region being adjacent to the fourth semiconductor region,
a depth of the first region from the first surface is greater than a depth of the second region from the first surface,
each second portion of the first insulating layer includes a third region and a fourth region, the third region being adjacent to the fourth semiconductor region, and
a depth of the third region from the first surface is greater than a depth of the fourth region from the first surface.

2. The semiconductor device according to claim 1, wherein the depth of the first region is between 1.1 and 1.5 times the depth of the second region.

3. The semiconductor device according to claim 1, wherein each first portion and second portion of the first insulating layer has a portion between a fourth semiconductor region and a portion of the first conductive layer in a second direction perpendicular to the first surface.

4. The semiconductor device according to claim 1, wherein a width of each fourth semiconductor region in the first direction is greater than a distance between otherwise adjacent first and second portions of the first insulating layer in the first direction.

5. The semiconductor device according to claim 1, wherein each portion of the first conductive layer has sub-portions spaced from each other in the first direction.

6. The semiconductor device according to claim 1, wherein a thickness of the first insulating layer in a second direction perpendicular to the first surface in the second region is less than or equal to a depth of the second region in the second direction.

7. The semiconductor device according to claim 1, wherein each portion of the first conductive layer is electrically connected to a fourth semiconductor region.

8. The semiconductor device according to claim 1, wherein the first conductive layer and the plurality of fourth semiconductor regions are electrically floating.

9. The semiconductor device according to claim 1, wherein
the termination region further includes a second conductive layer, and
each portion of the first conductive layer is between the second conductive layer and a fourth semiconductor region.

10. The semiconductor device according to claim 9, wherein the second conductive layer is electrically connected to the portion of the first conductive layer and the fourth semiconductor region.

11. The semiconductor device according to claim 1, wherein each fourth semiconductor region surrounds the element region in a plane parallel to the first surface.

12. The semiconductor device according to claim 1, wherein the first conductive layer surrounds the element region in a plane parallel to the first surface.

13. The semiconductor device according to claim 9, wherein the second conductive layer surrounds the element region in a plane parallel to the first surface.

14. The semiconductor device according to claim 1, wherein the first conductive layer is polycrystalline silicon.

15. The semiconductor device according to claim 1, wherein the termination region further includes:
a first insulating film between the portion of the first conductive layer and the fourth semiconductor region.

16. The semiconductor device according to claim 1, wherein the element region further includes:
a fifth semiconductor region of the second conductivity type between the first semiconductor region and the second surface and in contact with the second electrode.

17. The semiconductor device according to claim 1, wherein the element region further includes:
a trench extending into the semiconductor layer from the first surface, and
the gate electrode is in the trench.

18. The semiconductor device according to claim 1, wherein the semiconductor layer is silicon.

19. A method of manufacturing a semiconductor device, the method comprising:
forming a ring-shaped semiconductor region of a second conductivity type on a surface of a semiconductor layer of a first conductivity type by ion-implanting an impurity of the second conductivity type into the semiconductor layer,
forming a first trench inside the semiconductor region on the surface of the semiconductor layer,
forming a second trench outside the semiconductor region on the surface of the semiconductor layer, filling the first trench and the second trench with an insulating film,
performing heat treatment for activating the impurity in the semiconductor region,
forming a conductive film over the insulating film and the semiconductor region.

20. The method according to claim 19, wherein
the first trench and the second trench are in contact with the semiconductor region, and
a distance between the first trench and the second trench in a first direction outward from the semiconductor region is less than a width of the semiconductor region in the first direction.
